(19) United States
(12) Patent Application Publication
(10) Pub. No.: US 2008/0303683 A1
(43) Pub. Date: Dec. 11, 2008

(54) Economical force sensitive switch

(76) Inventor: Norman Victor Wheat, Thruscross (GB)

Correspondence Address: KAJANE MCMANUS, P.O.BOX 490, WONDER LAKE, IL, 60097, US

(21) Appl. No.: 11/811,213

(22) Filed: Jun. 8, 2007

(51) Int. Cl. H03K 17/96; G08B 21/00; H03K 17/94

(52) U.S. Cl. 340/686.2

(57) ABSTRACT

The economical force sensing switch comprising a housing and a movable member movable relative to the housing upon having a predetermined force applied thereagainst by an adjacent moving structure when the structure becomes misaligned, the movable member incorporating a set screw for engaging a microswitch within the housing at a predetermined position thereof to generate an alarm signal and will stop the adjacent structure from moving. A secondary optional thermal switch may also be incorporated.

### BACKGROUND OF THE INVENTION

1. Field of the Invention

The present invention relates to an economical force sensitive switch. More particularly, the switch, includes a microswitch assembly which is operative to stop a machine or the like, until a structure of the machine producing the force on the switch, is repositioned.

2. Prior Art

It has previously been proposed, in U.S. Pat. No. 6,731,219, owned by applicant, to provide a complex, expensive force sensitive switch comprising a housing and a movable member movable relative to the housing upon having a predetermined force applied thereagainst by an adjacent moving structure when the structure becomes misaligned, with the movable member engaging a load cell assembly within the housing which will produce an alarm signal and will stop the adjacent structure from moving.

It has been since determined that a less expensive, less complex functional embodiment can be created by replacing the load cell assembly of the prior embodiment, with a microswitch assembly, allowing use thereof in areas where economy is a concern.

### SUMMARY OF THE INVENTION

According to the invention there is provided an economical force sensing switch comprising a housing and a movable member movable relative to the housing upon having a predetermined force applied thereagainst by an adjacent moving structure when the structure becomes misaligned, the movable member being positionable relative to a microswitch, and acting thereon to engage the microswitch within the housing, to produce a visual indication and cause stoppage of motion of the adjacent structure. A secondary optional thermal switch may also be incorporated.

### BRIEF DESCRIPTION OF THE DRAWINGS

FIG. 1 is a cross sectional view through the switch of the present invention.

FIG. 2 is an exploded view of the switch of the present invention

FIG. 3 shows various circuits by which the visual indicator, in the form of an LED, can be actuated.

FIG. 4 is an exploded view of the switch of the present invention showing an optional secondary thermal switch incorporated therein.

FIG. 5 is a top plan view of the switch of FIG. 4.

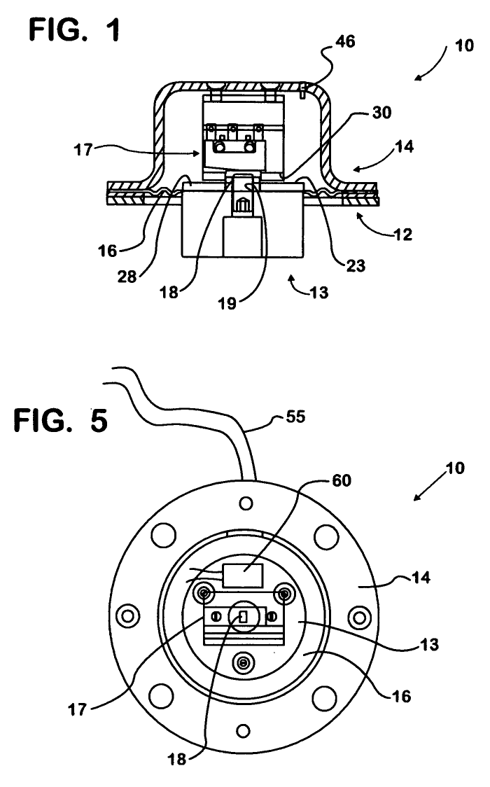

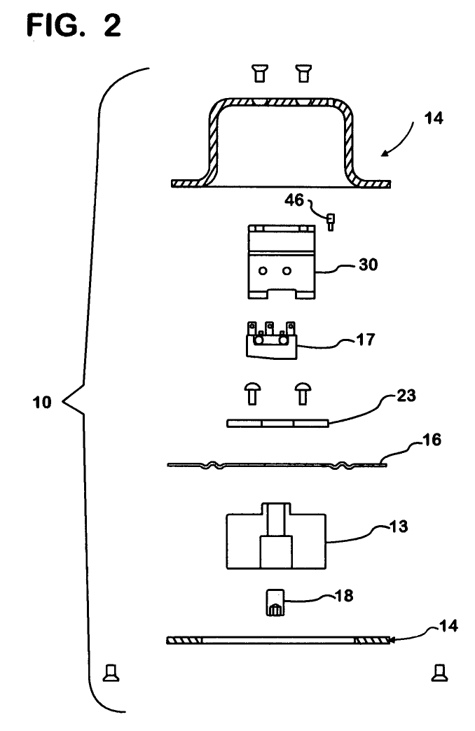

### DESCRIPTION OF THE PREFERRED EMBODIMENTS

Perusing the Figures in greater detail, it will be understood that the force sensitive switch made in accordance with the teachings of the present invention and generally identified by the reference numeral 10, comprises a body 12 made up of a rigid housing 14 made from metal or other substantially rigid material and a movable member 13 which is movable toward and away from the rigid housing 14, with a suitable flexible diaphragm 16 engaged therebetween.

Within the housing 14 is mounted an economical microswitch assembly 17. Acting on the microswitch 17 is a set screw 18 secured to the movable member 13 and suitably guided thereby through an opening 19, in the diaphragm 16, to permit force to act on the microswitch 17 in one direction only. The moveable member 13 is restrained from movement in directions other than the direction of action on the microswitch, by the diaphragm 16. It will be understood that the diagram 16 is preferably made of a metal, such as steel so that it is rigid in all directions of force except in the direction of actuation. Attached to the diaphragm 16 is the movable member 13 which may comprise a suitable button, plate, disc, arm, or sphere which may be hardened to resist the action of wear. A cover washer 23 positioned between the diagram 16 and the micro switch assembly 17 incorporates a surface 28 which will not allow the moveable member 13 to move excessively as it will be restrained by contact with a rigid stop 30 in the form of a switch bracket 30.

The assembly of the movable member 13 is so dimensioned that when the diaphragm 16 has been deflected to the design limits, and well before the elastic limit is exceeded, the surface 28 of the washer 23 contacts the rigid stop 30 which may be the bracket 30 supporting the microswitch 17 itself, and prevents further force on the movable member 13 from over-stressing the microswitch 17. When the rigid housing 14 of the switch 10 is mounted solidly to one part of a machine (not shown), misaligned motion of another part of the machine (not shown), adjacent the movable member 13, will cause a force to be applied to the movable member 13.

Therefore the switch 10 can be used to detect relative displacement or misalignment between two parts of a machine. This detection is particularly applicable, but not limited, to machines such as belt conveyors or belt elevators (not shown) where it is necessary to detect that movement of a belt of the machine into an undesirable or misaligned position has occurred. In such application, the switch 10 would be mounted to a rigid part of a machine in such a position that if the moving belt of the machine was misaligned laterally, it would generate a force onto and against the movable member 13 of the switch 10. In such application, the force sensing switch 10 may be arranged to warn of, or control, such an “out of bounds” condition.

The signal can produce a visual indication through the preferred LED 46, and can pass through a cable 55, suitably attached to the machine in known manner, to cause motion of the adjacent structure, such as the belt, to cease, upon misalignment.

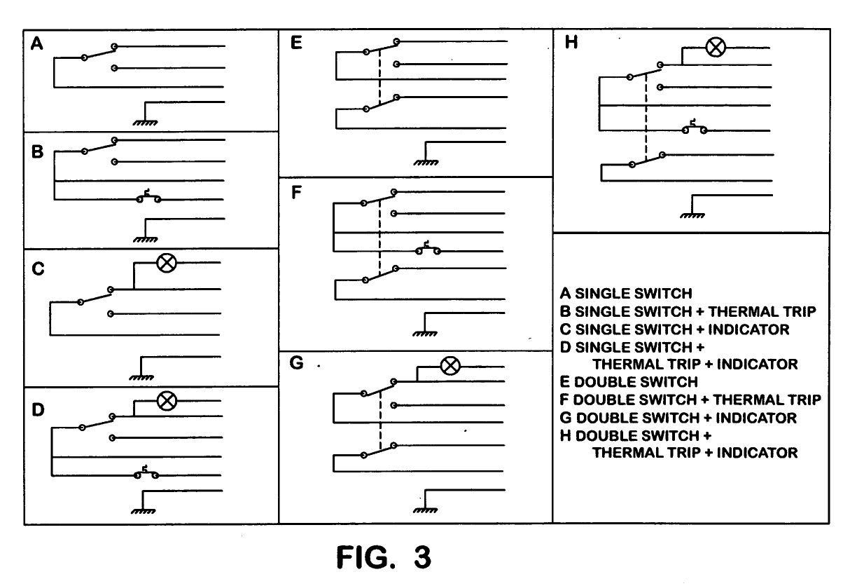

Various circuits capable of actuating the LED 46, for use in the switch 10, are illustrated in FIG. 3.

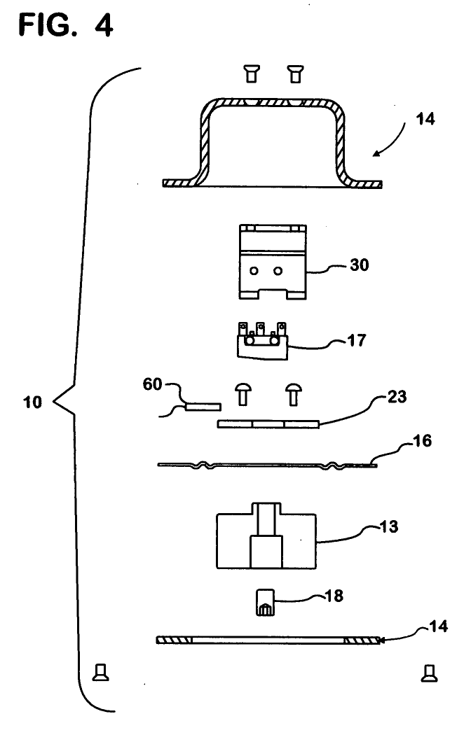

In FIGS. 4 and 5, a further embodiment of the switch 10 is illustrated wherein a secondary optional thermal switch 60 is incorporated therein. The thermal switch 60 can be fitted within the housing 14 to detect any temperature rise which may be caused by a slightly misaligned elevator or conveyor belt which rubs contiguously against the movable member 13 with sufficient force to cause frictional heating but without sufficient force to actuate the microswitch. In this way, the switch 10 can provide detection of varied conditions of force and misalignment. In this embodiment, the thermal switch 60 is preferably seated on and fixed to the washer 26.

One further point which may not be obvious from the description and drawings is that the diagram 16 is made out of steel or other metal so that it is rigid in all directions of force except in the direction of actuation of the switch 10.

It will also be understood by those skilled in the art that various structures of the circuitry described above may be mounted on a circuit board, if desired.

It will also be understood by those skilled in the art that the present embodiment is more economical than that previously proposed and therefore is available to a greater proportion of the purchasing public.

As described above, the force sensing switch 10 provides a number of advantages, some of which have been described above and others of which are inherent in the invention. Also, modifications may be proposed to the switch 10 without departing from the teachings herein. As an example, any simple, economical, equivalent structures, which could be used in place of the microswitch, should be considered within the scope of the teachings herein. Accordingly, the scope of the invention is only to be limited as necessitated by the accompanying claims.

1. An economical, simple force sensing switch comprising a housing and a movable member movable relative to the housing upon having a predetermined force applied thereagainst by an adjacent moving structure when the structure becomes misaligned, the movable member incorporating a set screw for engaging a microswitch within the housing, at a predetermined position thereof, to produce an alarm signal and stop the adjacent structure from moving.

2. The switch of claim 1 wherein the movable member comprises a button, a plate, an arm, a disc or a sphere.

3. The switch of claim 1 wherein the movable member is movable toward the housing when force is applied thereagainst.

4. The switch of claim 1 wherein a diaphragm is positioned between the housing and the movable member.

5. The switch of claim 1 wherein a diaphragm is positioned between the housing and the movable member and provides support, guidance, spring force and sealing of the assembly.

6. The switch of claim 1 wherein diaphragm is made of metal and a displacement of the diaphragm that is greater than the operating movement of the microswitch, will produce an alarm signal.

7. The switch of claim 6 wherein the alarm signal is in the form of a visual indication.

8. The switch of claim 6 wherein the alarm signal is in the form of an electrical signal which will cause the adjacent moving structure to stop moving.

9. The switch of claim 6 wherein the alarm signal is in the form of a visual indication and in the form of an electrical signal which will cause the adjacent moving structure to stop moving.

10. The switch of claim 1 further incorporating a secondary optional thermal switch therein.
